(19) United States
(12) Patent Application Publication
(10) Pub. No.: US 2010/0020372 A1
(43) Pub. Date: Jan. 28, 2010

(54) HOLOGRAPHIC RECORDING MEDIUM AND OPTICAL INFORMATION RECORDING/REPRODUCING APPARATUS

(75) Inventors: Satoshi MIKOSHIBA, Kanagawa (JP); Kazuki MATSUMOTO, Kanagawa (JP); Rumiko HAYASE, Kanagawa (JP); Norikatsu SASAO, Tokyo (JP); Takahiro KAMIKAWA, Tokyo (JP); Masahiro KANAMARU, Kanagawa (JP); Masaya TERAI, Kanagawa (JP)

Correspondence Address: Charles N.J. Ruggiero;Ohlandt, Greeley, Ruggiero & Perle, L.L.P., 10th Floor, One Landmark Square, Stamford, CT, 06901-2682, US

(73) Assignee: KABUSHIKI KAISHA TOSHIBA

(21) Appl. No.: 12/508,010

(22) Filed: Jul. 23, 2009

(30) Foreign Application Priority Data
Jul. 24, 2008 (JP) 2008-191021

(51) Int. Cl. G03H 1/02; G03F 7/00

(52) U.S. Cl. 359/3; 430/2

(57) ABSTRACT

A holographic recording medium is provided. The medium includes a recording layer. The recording layer includes a polymer matrix, a polymerizable monomer and a photopolymerization initiator. The polymerizable monomer includes a monomer being expressed in the following general formula (M1), (M2), or (M3).

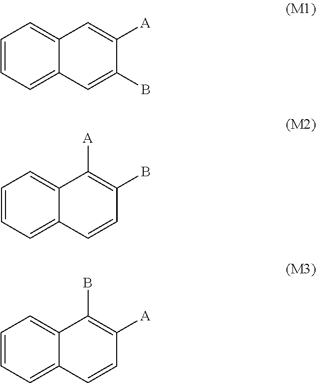

In the above general formulas, “A” and “B” denote a polymerizable substituent group and a nonpolymerizable substituent group, respectively.

### CROSS REFERENCE TO RELATED APPLICATION

This application is based upon and claims the benefit of priority from the prior Japanese Patent Application No. 2008-191021, filed on Jul. 24, 2008, the entire contents of which are incorporated herein by reference.

### FIELD OF THE INVENTION

The present invention relates to a holographic recording medium and an optical information recording/reproducing apparatus.

### DESCRIPTION OF THE BACKGROUND

A holographic memory which records information as a hologram is now attracting many attentions as a recording medium of the next generation as the memory is capable of performing a large capacity of recording. As the photosensitive composition for the holographic recording, it is known to employ a composition made of, as main components, a polymerizable monomer, a thermoplastic binder resin, a photo-radical polymerization initiator and a sensitizing dye.

This photosensitive composition for the holographic recording is prepared in a film to form a recording layer. Information is recorded in this recording layer through interference exposure. When the recording layer has been subjected to the interference exposure, the regions thereof which are strongly irradiated with light are allowed to undergo the polymerization reaction of the radical polymerizable monomer.

The radical polymerizable monomer diffuses from the regions where the intensity of exposure beam is weak to the regions where the intensity of exposure beam is strong, thereby generating the gradient of concentration in the recording layer. Namely, depending on the magnitude in intensity of the interference beam, differences in density of the radical polymerizable monomer occur, thereby generating a difference in refractive index in the recording layer.

JP-A 11-352303 (Kokai) discloses that a recording medium including a three-dimensional cross-linking polymer matrix with polymerizable monomers dispersed therein has been recently proposed. In such a holographic recording medium, it is pointed out as a problem that information is apt to be not stabilized after recording and the information deteriorates at the time of reproducing.

### SUMMARY OF THE INVENTION

According to a first aspect of the invention, a holographic recording medium includes a recording layer. The recording layer includes a polymer matrix, a polymerizable monomer and a photopolymerization initiator. The polymerizable monomer includes a monomer being expressed in the following general formula (M1), (M2), or (M3).

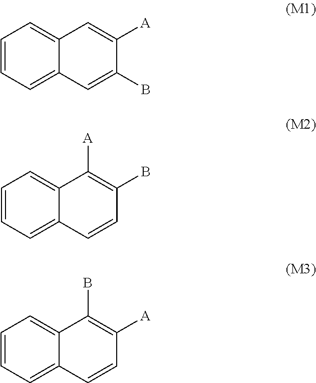

In the above general formulas, “A” and “B” denote a polymerizable substituent group and a nonpolymerizable substituent group, respectively.

According to a second aspect of the invention, an optical information recording/reproducing apparatus includes the holographic recording medium, a recording portion for recording information in the medium, and a reproducing portion for reproducing the information recorded in the medium.

### BRIEF DESCRIPTION OF DRAWINGS

The accompanying drawings, which are incorporated in and constitute a part of this specification, illustrate embodiments of the invention and together with the description, serve to explain the principles of the invention.

FIG. 1 is a sectional view schematically illustrating the holographic recording medium of a transmission-type hologram according to an embodiment of the invention.

FIG. 2 is a schematic view showing a transmission-type holographic information recording/reproducing apparatus.

FIG. 3 is a schematic sectional-view showing a reflection-type holographic recording medium.

FIG. 4 is a schematic view showing a reflection-type holographic information recording/reproducing apparatus.

FIG. 5 shows NMR data of 1-bromo-2-vinyl naphthalene.

FIG. 6 shows NMR data of 1-phenylthio-2-vinyl naphthalene.

### DETAILED DESCRIPTION OF THE EMBODIMENTS OF THE INVENTION

Embodiments of the present invention will be explained.

A recording layer in a holographic recording medium according to an embodiment of the present invention includes a polymer matrix, a polymerizable monomer, and a photopolymerization initiator. Particularly, the polymerizable monomer is expressed in either one of the following general formulas.

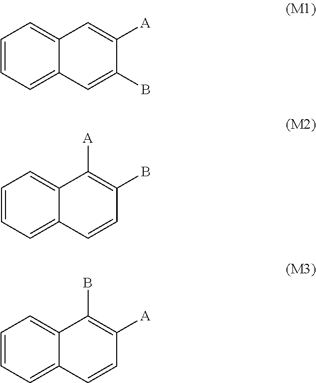

If interference light is incident onto such a recording layer, the photo polymerization initiator will react according to light intensity to polymerize the polymerizable monomer. As a result, the polymerizable monomer changes into an oligomer or a polymer in the recording layer.

Usually, a refractive index of the polymerizable monomer differs from that of the polymer matrix, and it is preferable that the refractive index of the polymerizable monomer is higher than that of the matrix. The refractive indexes of the polymerizable monomer are specifically 1.6 to 1.8, and it is preferable that the refractive index of the polymer matrix is 1.4 to 1.6.

The oligomer or the polymer distributes in accordance with distributions of light intensity, causing distributions of the refractive indexes. The photopolymerization initiator can remain at the end of recording in some cases. In such a case, all the remaining initiator can be polymerized by irradiating the medium with plane waves of LED, for example. Thus, the medium thus obtained after recording serves as a plastic having a refractive-index distribution finally inactive to light.

Information recorded as a hologram exists in the recording layer as the refractive-index distribution. When the polymer forming the refractive-index distribution is fluctuated by heat etc., and the distribution is disturbed, a degradation of the recording occurs. In order to obtain a recording with a long-term stability, it is required to suppress the thermal fluctuation of the polymer with the refractive-index distribution therein.

The polymer obtained conventionally by polymerizing polymerizable monomers has two portions composed of a main chain portion of hydrocarbon, and a portion of a substituent group. A rotational motion of the portion of the substituent group is enhanced by thermal energies in such a polymer. The main chain portion of the polymer with high and low flexibility of the portion of the substituent group has high and low flexibility, respectively. The inventors have focused on this point. That is, the lower the flexibility, the higher the glass-transition temperature of the polymer.

A polymer with low flexibility is obtained by suppressing the rotational motion of the portion of the substituent group thereof. In order to obtain such a polymer, the polymerizable monomer with a structure is required, the structure blocking the rotational motion of the portion of the substituent group.

The inventors have found out that a nonpolymerizable monomer is introduced into a specific area of the polymerizable monomer with a naphthalene framework to allow it to block the rotational motion of the portion of the substituent group therein. Such a polymerizable monomer is expressed in the following general formula (M1), (M2), or (M3).

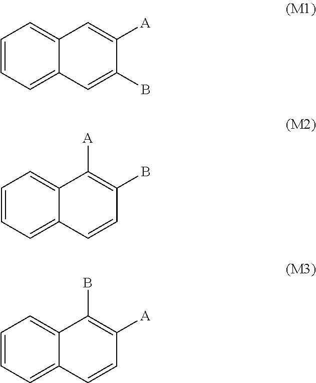

(In the above general formulas, “A” and “B” denote polymerizable and nonpolymerizable substituent groups, respectively.)

In any polymerizable monomer, the nonpolymerizable substituent group “B” binds chemically to a carbon atom adjacent to a carbon atom with the polymerizable substituent group “A” chemically binding thereto. After the polymerizable monomer is polymerized in the presence of the polymerizable substituent group “A”, the rotational motion of the nonpolymerizable substituent group “B” is blocked. The blocking of this motion also lowers the flexibility of the portion of the substituent group.

As a result, the low flexibility of the main chain portion lowers the flexibility of the whole polymer, thereby heightening the glass transition temperature. This leads to a thermal stability of the medium recorded, allowing it to realize a stable recording over the long term.

In order to fully achieve the blocking effect of the motion, it is preferable that the nonpolymerizable substituent group “B” is bulky. Specifically, the bulky substituent groups include substituted or unsubstituted alkyl group, substituted or unsubstituted aromatic group, halogen group, substituted or unsubstituted sulfinyl group, sulfonyl group, substituted or unsubstituted sulfoxide group, substituted or unsubstituted alkyloxy group, and substituted or unsubstituted aromatic oxy group. Moreover, in order to obtain monomers with a high refractive index, it is required that the refractive indexes of the substituent groups are also high.

Taking these into consideration, preferable nonpolymerizable substituent groups “B” include a bromo group, a methyl sulfenyl group, a phenyl sulfenyl group, a naphthyl sulfinyl group, a methyl sulfinyl group, a phenyl sulfinyl group, a naphthyl sulfinyl group, a methyl sulfonyl group, and a phenyl sulfonyl group. When hydrogen atoms are contained in the nonpolymerizable substituent group, a portion of the atoms may be substituted by a halogen group, a hydroxyl group, a thiol group, an ether group, a thioether group, etc.

On the other hand, the polymerizable substituent groups “A” are not limited particularly, while a vinyl group, an acrylics group, a methacryl group, an epoxy group, an oxetane group, etc. may be employed.

In the naphthalene framework, a substituent group may be introduced into carbon atoms other than the carbon atoms with the polymerizable substituent groups “A” and “B” chemically binding thereto. Considering the thermal stability and durability after recording, the substituent groups introduced preferably include an aromatic group, a halogen group, an aromatic sulfide group, an aromatic oxy group, etc. and the substituent groups is required to be located at any one of the first to fourth carbon positions of naphthalene.

The storage density is dependent on the content of the polymerizable monomers in the recording layer. Therefore, as long as the optical recording formed by polymerizing is not destroyed, it is more preferable that a larger amount of the polymerizable monomer is contained in the recording layer.

The content of the polymerizable monomer in the recording layer should preferably be confined to the range of 1 to 40 weight % of the recording layer. If the content of the polymerizable monomer is less than 1 weight %, the recording density may be extremely deteriorated. Furthermore, owing to an excessive content of the polymer matrix, the mobility of the polymerizable monomer may be obstructed, resulting in the deterioration of recording sensitivity. On the other hand, if the content of the radical polymeric monomer exceeds 40 weight %, the optical recording that has been created may be easily deformed due to the relatively small content of the polymer matrix. In that case, it may become difficult to read out the information that has been recorded in the recording layer. More preferably, the content of the radical polymeric monomer should be confined to 5 to 15 weight % of the recording layer.

In addition to the above-mentioned polymerizable monomers, second polymerizable monomers may be contained. The second polymerizable monomers include vinyl naphthalene, vinyl carbazole, a tribromo phenyl acrylate, and other polymerizable monomers such as tribromo phenyl methacrylate. Two or more kinds of the second polymerizable monomers may be employed, and their contents are not limited in particular.

It is preferable that the polymer matrix includes a three-dimensional cross-linking polymer. The three-dimensional cross-linking polymer may be formed by arbitrary reactions. The reactions are not limited in particular. The reactions include a reaction of isocyanate with a hydroxyl group, a reaction of α, β unsaturated carbonyl with thiol and a ring-opening cationic reaction of epoxy and oxetane, etc. Among the above-described reactions, the ring-opening cationic reactions such as epoxy-amine polymerization, epoxy-acid anhydride polymerization, ring-opening cationic reactions such as epoxy homopolymerization and oxetane homopolymerization are preferable. Furthermore, ring-opening cationic polymerization is more preferable, and epoxy homopolymerization with aluminum complex and silanol as catalysts is the most preferable.

As the amine to be employed for the epoxy-amine polymerization, it is possible to employ any kind of amine compound selected from the group consisting of 1,6-hexane dioldiglycidyl ether and diethyleneglycol diglycidyl ether. The amine compound is capable of producing a cured substance through a reaction thereof with diglycidyl ether.

More specifically, examples of the amine include ethylenediamine, diethylenetriamine, triethylenetetramine, tetraethylenepentamine, pentaethylenehexamine, hexamethylenediamine, menthenediamine, isophoronediamine, bis(4-amino-3-methyldicyclohexyl)methane, bis(aminomethyl)cyclohexane, N-aminoethyl piperazine, m-xylylene diamine, 1,3-diaminopropane, 1,4-diaminobutane, trimethylhexamethylene diamine, iminobispropyl amine, bis(hexamethylene)triamine, 1,3,6-trisaminomethylhexane, dimethylaminopropyl amine, aminoethyl ethanol amine, tri(methylamino) hexane, m-phenylene diamine, p-phenylene diamine, diaminodiphenyl methane, diaminodiphenyl sulfone, 3,3′-dietheyl-4,4′-diaminodiphenyl methane, etc.

Since aliphatic primary amine can be cured quickly at room temperature, it can be preferably employed. Among them, diethylene triamine, triethylene tetramine, tetraethylene pentamine, pentaethylene hexamine and iminobispropyl amine are particularly preferable. The mixing ratio of these amines relative to the oxirane of 1,6-hexanediol diglycidyl ether or diethylene glycol diglycidyl ether should preferably be confined to such that the NH— of amine is 0.6 time to twice as high as the equivalent weight. When this mixing ratio of these amines is less than 0.6 time or more than twice the equivalent weight, the resolution may be deteriorated.

As the epoxy monomer, it is possible to employ, for example, glycidylether. More specifically, examples of the epoxy monomer include ethylene glycol diglycidyl ether, 1,4-butane dioldiglycidyl ether, 1,5-pentane dioldiglycidyl ether, 1,6-hexane dioldiglycidyl ether, 1,8-octane dioldiglycidyl ether, 1,10-decane dioldiglycidyl ether, 1,12-dodecane dioldiglycidyl ether, etc.

The epoxy homopolymerization can be done through the cationic polymerization of epoxy monomer. As examples of the epoxy monomer useful in this case, they include ethyleneglycol diglycidyl ether, 1,4-butane dioldiglycidyl ether, 1,5-pentane dioldiglycidyl ether, 1,6-hexane dioldiglycidyl ether, 1,8-octane dioldiglycidyl ether, 1,10-decane dioldiglycidyl ether, 1,12-dodecane dioldiglycidyl ether, etc.

Considering mobility of a ring-opening polymerizable monomer, the epoxy monomer should preferably be selected from the compounds represented by the following general formula (1).

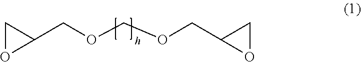

(In the general formula (1), h is an integer ranging from 8 to 12.)

Specific examples of the compounds represented by the general formula (1) include 1,4-butane dioldiglycidyl ether, 1,5-pentane dioldiglycidyl ether, 1,6-hexane dioldiglycidyl ether, 1,8-octane dioldiglycidyl ether, 1,10-decane dioldiglycidyl ether and 1,12-dodecane dioldiglycidyl ether.

The cationic polymerization of the epoxy monomer can be carried out using a metal complex and alkyl silanol both acting as a catalyst.

As the metal complex, it is possible to employ the compounds represented by the following general formulas (2), (3) and (4):

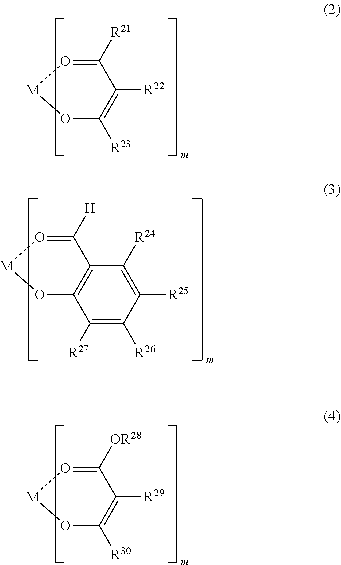

(In the general formulas (2), (3) and (4), M is selected from the group consisting of Al, Ti, Cr, Mn, Fe, Co, Ni, Cu, Zr, Zn, Ba, Ca, Ce, Pb, Mg, Sn and V; R²¹, R²² and R²³ may be the same or different and are individually hydrogen atom, substituted or unsubstituted alkyl group having 1 to 10 carbon atoms; R²⁴, R²⁵, R²⁶ and R²⁷ may be the same or different and are individually hydrogen atom, substituted or unsubstituted alkyl group having 1 to 10 carbon atoms; R²⁸, R²⁹ and R³⁰ may be the same or different and are individually hydrogen atom, substituted or unsubstituted alkyl group having 1 to 10 carbon atoms; and m is an integer of 2 to 4.)

When the compatibility of the metal complex with the three-dimensional cross-linking polymer matrix and the catalytic capacity thereof are taken into consideration, the M in these general formulas (2), (3) and (4) should preferably be selected from aluminum (Al) and zirconium (Zr), and R²¹ to R³⁰ should preferably be selected from alkylacetylacetate such as acetylacetone, methylacetylacetate, ethylacetylacetate, propylacetylacetate, etc. Among them, the most preferable metal complex is aluminum tris(ethylacetylacetate).

As the alkyl silanol, it is possible to employ compounds represented by the following general formula (5).

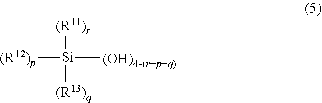

(In the general formula (5), R¹¹, R¹² and R¹³ may be the same or different and are individually substituted or unsubstituted alkyl group having 1 to 30 carbon atoms, substituted or unsubstituted aromatic group having 6 to 30 carbon atoms, or substituted or unsubstituted aromatic heterocyclic group having 3 to 30 carbon atoms; and p, q and r are individually an integer of 0 to 3 with the proviso that p+q+r is 3 or less.)

As examples of the alkyl group to be introduced as R¹¹, R¹² and R¹³ into the general formula (5), they include, for example, methyl, ethyl, propyl, butyl, pentyl, hexyl, etc. As examples of the aromatic group to be introduced as R¹¹, R¹² and R¹³, they include, for example, phenyl, naphthyl, tolyl, xylyl, cumenyl, mesityl, etc. As examples of the aromatic heterocyclic group to be introduced, they include, for example, pyridyl, quinolyl, etc. At least one of hydrogen atoms in these alkyl group, aromatic group and aromatic heterocyclic group may be substituted by a substituent group such as halogen atom, etc.

More specific examples of alkylsilanol include diphenyldisilanol, triphenylsilanol, trimethylsilanol, triethylsilanol, diphenylsilanediol, dimethylsilanediol, diethylsilanediol, phenylsilanediol, methylsilanetriol, ethylsilanetriol, etc. When the compatibility of alkylsilanol with the three-dimensional cross-linking polymer matrix and the catalytic capacity thereof are taken into consideration, the employment of diphenyldisilanol or triphenylsilanol is preferable as the alkylsilanol.

The phenolic compound represented by the following general formula (6) can be employed as a compound having almost the same effects as the alkyl silanol represented by the above-mentioned general formula (5).

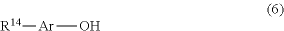

(In the general formula (6), R¹⁴ is substituted or unsubstituted alkyl group having 1 to 30 carbon atoms, or substituted aromatic group having 6 to 30 carbon atoms; and Ar is substituted or unsubstituted aromatic group having 3 to 30 carbon atoms.)

As examples of the alkyl group to be introduced as R¹⁴ into the general formula (6), they include, for example, methyl, ethyl, propyl, butyl, pentyl, hexyl, trifluoromethyl, pentafluoroethyl, etc. At least one of hydrogen atoms in the alkyl group may be substituted by a substituent group such as halogen atoms, etc.

As examples of the substituted aromatic group to be introduced as R¹⁴, they include, for example, HO(C₆H₆)SO₂—, HO(C₆H₆)C(CH₃)₂—, —HO(C₆H₆)CH₂—, etc.

As examples of the aromatic group to be introduced as Ar, they include, for example, phenyl, naphthyl, tolyl, xylyl, cumenyl, mesityl, etc. At least one of hydrogen atoms in the aromatic group may be substituted by the above-mentioned substituent group.

Since the phenolic compound represented by the above-mentioned general formula (6) is capable of executing substitution reaction with the ligand of the metal complex, the phenolic compound is enabled to exhibit almost the same effects as the alkyl silanol represented by the above-mentioned general formula (5).

As examples of the phenolic compound represented by the above-mentioned general formula (6), they include HO(C₆H₆) SO₂ (C₆H₆) OH, HO(C₆H₆) CH₂ (C₆H₆) OH, HO(C₆H₆) C(CH₃)₂(C₆H₆) OH, CF₃(C₆H₆) OH, CF₃CF₂ (C₆H₆) OH, etc. When the compatibility of phenolic compound with the three-dimensional cross-linking polymer matrix and the catalytic capacity thereof are taken into consideration, the employment of CF₃ (C₆H₆) OH or HO(C₆H₆) SO₂ (C₆H₆) OH is preferable as the phenolic compound.

A cationic polymerization catalyst which is composed of a combination of the alkyl silanol represented by the above-mentioned general formula (5) and the metal complex represented by any one of the above-mentioned general formulas (2), (3) and (4) is capable of proceeding the polymerization reaction of the polymerizable monomer at room temperature (around 25° C.). Therefore, it is possible to form the three-dimensional cross-linking polymer matrix without applying thermal history to the polymerizable monomer and to the photopolymerization initiator. The three-dimensional cross-linking polymer matrix formed can be represented with the following general formula (7).

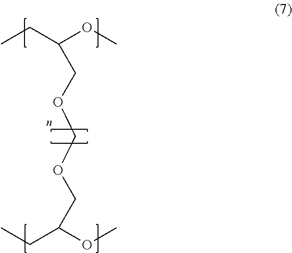

(In the general above-mentioned formula (1), n is an integer ranging from 3 to 16.)

Even when the alkyl silanol is replaced by the phenolic compound represented by the above-mentioned general formula (6), almost the same effects as described above can be obtained.

Moreover, the catalytic components such as the alkyl silanol represented by the above-mentioned general formula (5), the phenolic compound represented by the above-mentioned general formula (6) and the metal complex represented by any one of the above-mentioned general formulas (2), (3) and (4) are enabled to exist in the three-dimensional cross-linking polymer matrix without reacting with this polymer matrix obtained through the polymerization. Furthermore, no ionic impurities can be generated.

When a predetermined region of the recording layer including the three-dimensional cross-linking polymer matrix, the polymerizable monomer and the photopolymerization initiator is irradiated with light to expose the recording layer, the polymerizable monomer is caused to move to the exposed region. The space created by this movement of the polymerizable monomer is then occupied by the catalytic components existing in the polymer matrix. As a result, the change in refractive index becomes more prominent.

Even if a reaction between the catalytic components occurs, there would be raised no problem. It is possible to prevent rapid reactions and hence to retard the reaction rates, resulting in easiness to control the shrinkage and strain of the recording medium. Accordingly, it is more preferable to employ the phenolic compound represented by the general formula (6) rather than the alkyl silanol represented by the general formula (5).

Furthermore, these catalytic components do not generate decomposition products such as alcohol or impurities. Water is not required to be existed in the recording medium when effecting the catalytic action, and therefore it is possible to employ a recording medium in a stable dried state.

The catalytic components, such as the metal complex and alkyl silanol described above, act to strengthen the adhesion between the substrate sustaining the recording medium and the recording layer. When a molecule highly polarized therein such as the metal complex co-exists with the hydroxyl group of silanol in the recording layer, the adhesion of the recording layer to various kinds of substrates such as those made of glass, polycarbonate, acrylic resin, polyethylene terephthalate (PET), etc., can be enhanced.

When the adhesion of the recording layer to the substrate is enhanced, it is possible to prevent peel-off of the recording layer even if the shrinkage or expansion of volume occurs at a tiny exposed region or unexposed region when writing information with interference light wave. Since the information thus recorded can be retained without any distortion, it is possible to further enhance the recording performance. Furthermore, the metal complex and alkyl silanol exist in the polymer matrix without deactivation.

For this reason, the information thus written can be fixed through the post-baking of the recording medium, thus allowing it to prevent the information from changing with time. When the recording medium is subjected to exposure to interference light wave, the polymerizable monomer polymerizes to increase the density of the exposed region, thus heightening the refractive index. On the other hand, at the unexposed region, the density thereof is reduced owing to the movement of the polymerizable monomer therefrom, thus decreasing the refractive index. The polymerizable monomer in this case can be easier to move as the polymer matrix of the recording medium is lower in density. Namely, as the crosslink density of the three-dimensional cross-linking polymer matrix becomes lower, the polymerizable monomer can be easier to move, thus producing a recording medium with higher sensitivity.

However, in the case of the three-dimensional cross-linking polymer matrix with a low crosslink density, the polymerizable monomer or the polymer thereof tends to move into an unexposed region which is spatially low in density. Therefore, the crosslink density of the polymer matrix should preferably be decreased so as to allow the polymerizable monomer to easily move when recording information through the exposure of recording layer to an interference light wave. After the information has been written in the recording layer, however, when the information is desired to be fixed, it will be effective to enhance the crosslink density of the polymer matrix by post-baking. Since the recording medium according to the embodiment is enabled to increase the crosslink density of the polymer matrix by post-baking, the recording performance of the recording medium can be enhanced.

The post-baking should preferably be performed at a temperature ranging from 40° C. to 100° C. If the temperature of post-baking is lower than 40° C., it may become difficult to increase the crosslink density of the polymer matrix. On the other hand, if the temperature of post-baking exceeds 100° C., the molecular motion of the polymer matrix would be activated, thereby possibly making it impossible to read out the recorded information.

As described above, when recording the information with an interference light wave, the density of the recording layer increases at the exposed region, while the density of the unexposed region is reduced. Owing to a difference in density of the recording layer, the catalytic components such as the metal complex and alkyl silanol move from the exposed region to the unexposed region. This movement of these catalytic components promotes the moving of the polymerizable monomer to the exposed region. Furthermore, the catalytic components that have been moved to the unexposed region of the recording layer act to lower the refractive index of the unexposed region thereof.

The three-dimensional cross-linking polymer matrix (a cured product of epoxy resin) that has been polymerized using the metal complex and alkyl silanol as catalysts is transparent to light ranging from visible light to ultraviolet radiation, and has an optimal hardness. Namely, since the polymer matrix is transparent to an exposure wavelength, the absorption of light by the photopolymerization initiator cannot be obstructed, thereby allowing it to obtain a three-dimensional cross-linking polymer matrix having a suitable degree of hardness for enabling the polymerizable monomer to appropriately diffuse therein. As a result, it is now possible to manufacture a holographic recording medium which is excellent in sensitivity and diffraction efficiency. Furthermore, since the three-dimensional cross-linking polymer matrix has a suitable degree of hardness, it is possible to inhibit the recording layer from being shrunk at the region where the polymerization of the polymerizable monomer has taken place.

The employment of the above-mentioned epoxy monomer in the formation of the three-dimensional cross-linking polymer matrix is advantageous in the following respects. Namely, when the above-mentioned epoxy monomer is employed, it is possible to obviate any possibility of obstructing the moving of the polymerizable monomer to be generated on the occasion of exposure. The reasons for this can be explained as follows. First of all, it is possible to secure a sufficient space for enabling the polymerizable monomer to move in the three-dimensional cross-linking polymer matrix. There is little possibility of locally enhancing the crosslink density. Furthermore, since the polarity of the polymer matrix is low, the movement of the polymerizable monomer cannot be obstructed. Therefore, it is now possible to perform the excellent write-in of hologram.

In addition to the above-mentioned polymerizable monomer and polymer matrix, the photopolymerization initiator is included in the recording layer of the holographic recording medium according to the embodiment.

As the photopolymerization initiator, it is possible to employ, for example, imidazole derivatives, organic azide compounds, titanocene, organic peroxides, and thioxanthone derivatives. Specific examples of the photopolymerization initiator include benzyl, benzoin, benzoin ethyl ether, benzoin isopropyl ether, benzoin butyl ether, benzoin isobutyl ether, 1-hydroxycyclohexyl phenyl ketone, benzyl methyl ketal, benzyl ethyl ketal, benzyl methoxyethyl ether, 2,2′-diethylacetophenone, 2,2′-dipropylacetophenone, 2-hydroxy-2-methylpropiophenone, p-tert-butyltrichloroacetophenone, thioxanthone, 2-chlorothioxanthone, 3,3′,4,4′-tetra(t-butyl peroxycarbonyl)benzophenone, 2,4,6-tris(trichloromethyl) 1,3,5-triazine, 2-(p-methoxyphenyl)-4,6-bis(trichloromethyl)1,3,5-triazine, 2-[(p-methoxyphenyl)ethylene]-4,6-bis(trichloromethyl) 1,3,5-triazine, Irgacure 149, 184, 369, 651, 784, 819, 907, 1700, 1800, 1850 (Chiba Speciality Chemicals Co., Ltd.), di-t-butyl peroxide, dicumyl peroxide, t-butylcumyl peroxide, t-butyl peroxyacetate, t-butyl peroxyphthalate, t-butyl peroxybenzoate, acetyl peroxide, isobutyryl peroxide, decanoyl peroxide, lauroyl peroxide, benzoyl peroxide, t-butyl hydroperoxide, cumene hydroperoxide, methylethyl ketone peroxide, cyclohexanone peroxide, etc.

These photopolymerization initiators should preferably be added to the raw material solution at a content ranging from 0.1 to 10% by weight on the polymerizable monomer. If the content of these photopolymerization initiators is less than 0.1% by weight, it may become impossible to obtain a sufficient change in refractive index. On the other hand, if the content of these photopolymerization initiators exceeds 10% by weight, the light absorption by the recording layer would become too large, thus possibly deteriorating the resolution. More preferably, the content of the photopolymerization initiator should be confined to 0.5 to 6% by weight on the polymerizable monomer.

If necessary, a sensitizing dye such as cyanine, merocyanine, xanthene, coumalin, eosin, etc., a silane coupling agent and a plasticizer may be added to the raw material solution for the recording layer.

Predetermined components mentioned above are mixed together to prepare a raw material solution for the recording layer. Using the raw material solution thus prepared for the recording layer, a resin layer is deposited on the predetermined substrate and then the polymer matrix is created, thus forming the recording layer.

For example, the raw material solution for the recording layer is coated on the light transmissive substrate to form a resin layer. As the light transmissive substrate, it is possible, for example, a glass substrate or a plastic substrate. The coating of the raw material solution can be performed by casting or spin-coating method. Alternatively, the raw material solution for the recording layer may be poured into a space formed between a pair of superimposed glass substrates with a resin spacer being interposed therebetween, thus forming the resin layer.

The resin layer thus formed is then heated using an oven, a hot plate, etc. to allow the polymerization of the epoxy monomer to proceed, thus forming the three-dimensional cross-linking polymer matrix. The temperature in this heating step should be confined within a range of 10° C. to less than 80° C., more preferably 10° C. to less than 60° C. If this heating temperature is lower than 10° C., it may become difficult to create the three-dimensional cross-link. On the other hand, if this heating temperature is 80° C. or more, the polymerization reaction may become vigorous, thereby narrowing the voids of the three-dimensional cross-linking polymer matrix, so that the moving velocity of the polymerizable monomer in the polymer matrix may be reduced. Furthermore, if this heating temperature is 80° C. or more, the reaction of the polymerizable monomer may possibly take place. Since this reaction can take place sufficiently even at room temperature, it is preferable to employ a method to cure the resin layer at room temperature.

As the film thickness of the recording layer, it should preferably be confined within a range of 0.1 to 5 mm. If the film thickness of the recording layer is less than 0.1 mm, the angular resolution may deteriorate, thereby making it difficult to perform multiple recording. On the other hand, if the film thickness of the recording layer exceeds 5 mm, the transmissivity of the recording layer may be reduced, thus deteriorating the performance of the recording layer. More preferably, the film thickness of the recording layer should be confined within a range of 0.2 to 2 mm.

When performing the recording in the holographic recording medium according to the embodiment, the recording medium is irradiated with the information beam and the reference beam. By enabling these two beams to interfere in the inside of the recording layer, the recording or the reproduction of the hologram is performed. As the type of hologram (holography) to be recorded, it may be either a transmission-type hologram (transmission-type holography) or a reflection-type hologram (reflection-type holography). In order to generate the interference between the information beam and the reference beam, a two-beam interference method or a coaxial interference method may be employed.

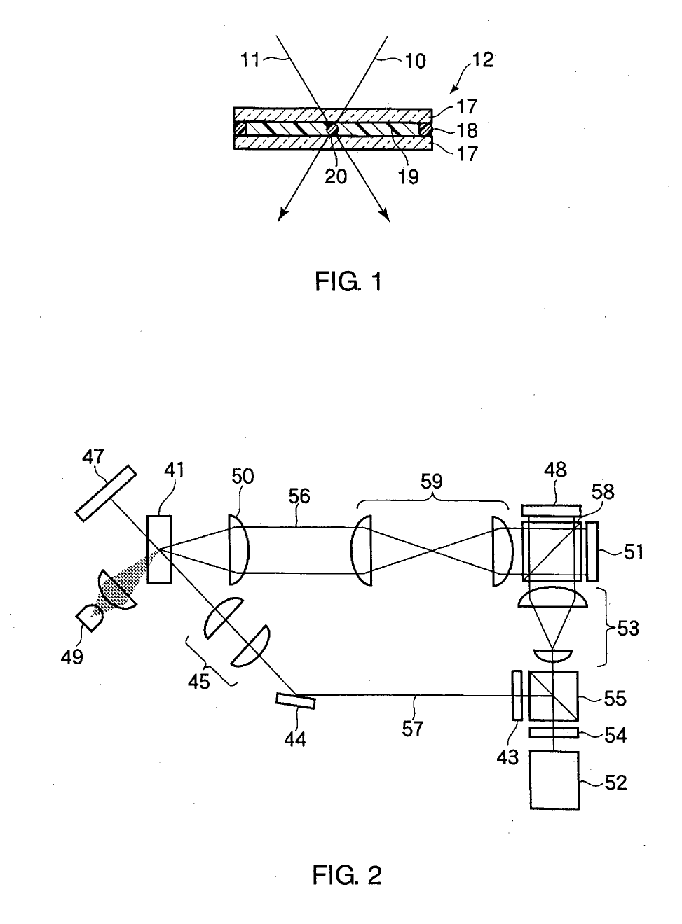

FIG. 1 shows a schematic view illustrating the holographic recording medium to be employed for the two-beam interference holography and also illustrating the information beam and the reference beam in the vicinity of the holographic recording medium to be irradiated therewith. As shown in FIG. 1, a holographic recording medium 12 is provided with a pair of transparent substrates 17, between which a spacer 18 and a recording layer 19 are sandwiched. The transparent substrates 17 are respectively made of glass or plastics such as polycarbonate. A recording layer 19 includes a specific kind of three-dimensional cross-linking polymer matrix as mentioned above, a polymerizable monomer, and a photopolymerization initiator.

When the holographic recording medium 12 is irradiated with an information beam 10 and a reference beam 11, these beams are intersected in the recording layer 19. As a result, interference takes place between these beams, thereby creating a transmission-type hologram in a modulated region 20.

FIG. 2 is a schematic view illustrating an example of a holographic information recording/reproducing apparatus. The holographic information recording/reproducing apparatus shown in FIG. 2 is an optical information recording/reproducing apparatus where a transmission-type two-beam interference method is utilized.

The beam emitted from a light source device 52 is introduced, via an optical element 54 for optical rotation, into a polarized beam splitter 55. As the light source device 52, it is possible to employ a GaN type semiconductor laser. The light source device emits coherent light with a wavelength of 405 nm.

As the optical element 54 for optical rotation, a half-wavelength plate for a wavelength of 405 nm may be employed. The orientation of the half-wavelength plate is adjusted so that a contrast of the hologram recorded in the transmission-type recording medium is the highest.

The light that has been introduced into a polarized beam splitter 55 is divided into two beams. One beam of the two is introduced into a polarized beam splitter 58 via a beam expander 53, information being given thereto by a reflection-type spatial beam modulator 51. The one beam is directed onto a transmission-type holographic recording medium as an information beam 56 passing through a relay lens 59 and an objective lens 50. As the reflection-type spatial beam modulator 51, a reflective liquid crystal panel may be employed.

In addition, the numeric 48 denotes a two-dimensional optical power detector, and a CCD array may be employed for it.

The other beam divided by the polarized beam splitter 55 passes through an optical element 43 for optical rotation to serve as a reference beam 57. As the optical element 43 for optical rotation, a half-wavelength plate for a wavelength of 405 nm can be used. The orientation of the half-wavelength plate is adjusted so that the polarization directions of the information and reference beams 56 and 57 are equal to each other in a transmission-type holographic recording medium 41. Passing through a mirror 44 and a relay lens 45, this reference beam is directed onto the transmission-type holographic recording medium 41.

In order to stabilize the hologram that has been recorded through the polymerization of unreacted polymerizable monomer, ultraviolet light may be directed thereto using an ultraviolet source device 49 after the holographic recording, polymerizing unreacted ring-opening polymerizable monomer. As the ultraviolet light, it is possible to employ any kind of light that can be effective in polymerizing the unreacted ring-opening polymerizable monomer. Because of excellence in ultraviolet light-emitting efficiency, it is preferable to employ, for example, a xenon lamp, a mercury lamp, a high-pressure mercury lamp, a mercury xenon lamp, a gallium nitride-based light-emitting diode, a gallium nitride-based semiconductor laser, an excimer laser, a tertiary harmonics (355 nm) of Nd:YAG laser, and a quaternary harmonics (266 nm) of Nd:YAG laser.

For recording on the medium using the apparatus illustrated, the transmission-type holographic recording medium is first mounted in the holographic information recording/reproducing apparatus. The recording is executed using an angular multiple recording/reproduction technique. According to the technique, an incident angle of the reference beam is varied with respect to every page by driving the mirror 44. The recording characteristic is evaluated using reproduced images under the following conditions:

a recording spot is 3 mm in radius;

an angle interval of the reference beam is 0.5°; and

a multiplicity per spot has 40 pages.

Beam intensity on the surface of the optical medium 41 can be adjusted to be, e.g., 0.5 mW, and the exposure time to be one second. In the reflection-type spatial beam modulator 51, only an information beam region 71 was shown as follows. This information beam region is provided with 20736 pixels, i.e. 144×144 (20376 pixels), within which 16 pixels, (i.e., 4×4), is treated as a unit panel, information processing is executed totally as 1296 panels. As a mode of expression for information, a 16:3 modulation method to treat 3 pixels of 16 pixels (i.e., 4×4) as bright pixels is employed, being capable of expressing 256 kinds (1 byte) with one panel, i.e., 1296 bytes per page as a total volume of information.

The recorded hologram can be reproduced by a CCD array 48. For reproducing, the optical element 54 for optical rotation is rotated so that the optical medium 41 is irradiated with only the reference beam 57. The mirror 47 is adjusted so that the reference beam 57 may be reflected perpendicularly, and the orientation of the optical element 43 for optical rotation is adjusted so that intensity of the reproduced beam is highest. The light intensity in the optical recording medium can be, e.g., 0.5 mW at the time of reproducing.

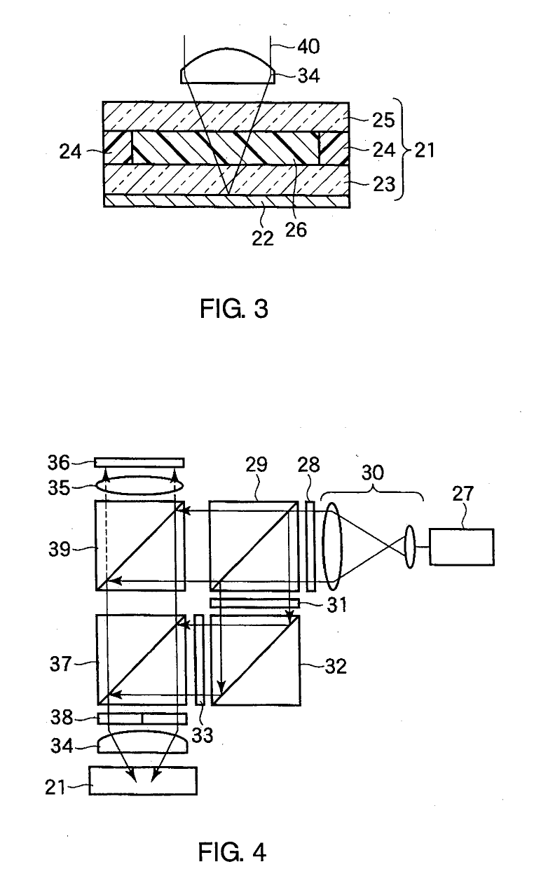

The recording medium according to the embodiment of the invention may be used also as a reflection-type holographic recording medium. In this case, for example, recording is performed as shown in FIG. 3. FIG. 3 is a schematic view showing the reflection-type holographic recording medium, and two beams in the vicinity thereof, the two beams being the information beam and reference beam. As shown in FIG. 3, a holographic recording medium 21 is provided with a pair of transparent substrates 23 and 25, between which a spacer 24 and a recording layer 26 are sandwiched, and a reflecting layer 22 supported by the substrate 23. The transparent substrates 23 and 25 are respectively made of glass or plastics such as polycarbonate. A recording layer 26 includes a specific kind of three-dimensional cross-linking polymer matrix as mentioned above, a polymerizable monomer, and a photopolymerization initiator.

When the recording layer 26 is irradiated with an information beam and a reference beam 40, these beams are intersected in the recording layer 26. As a result, interference takes place between these beams, thereby creating a reflection-type hologram in the modulated region (not shown in the figure) of the reflection-type holographic medium 21 as well as in the case of the transmission-type hologram.

A method for recording to the reflection-type holographic recording medium 21 is explained with reference to FIG. 4.

It is preferable to employ a laser to emit linearly-polarized light as a light source device 27 in a holographic recording/reproducing apparatus shown in the figure. As the laser, it is possible to employ a semiconductor laser, a He—Ne laser, an Ar laser and a YAG laser.

The beam emitted from the light source device 27 is expanded in beam diameter by a beam expander 30 and then incident on an optical element 28 for optical rotation as a parallel beam.

The optical element 28 for optical rotation emits, through the rotation of the plane of polarization of the previous beam of light, a beam including a polarized beam component where the plane of polarization is parallel to the plane of drawing (hereinafter referred to as a P-polarized beam component) and a polarized beam component where the plane of polarization is perpendicular to the plane of drawing (hereinafter referred to as a S-polarized beam component). Alternatively, it is possible to enable the optical element 28 to emit, by making the previous beam of light into a circularly polarized light or an elliptically polarized light, a beam including a polarized beam component where the plane of polarization is parallel to the plane of drawing and a polarized beam component where the plane of polarization is perpendicular to the plane of drawing. As the optical element 28 for optical rotation, it is possible to employ, for example, a half- or quarter-wavelength plate.

Among these beams that have been emitted from the optical element 28, the S-polarized beam component is reflected by a polarized beam splitter 29 and hence transmitted to a transmission-type spatial beam modulator 31. Meanwhile, the P-polarized beam component passes through the polarized beam splitter 29. This P-polarized beam component is utilized as a reference beam.

The transmission-type spatial beam modulator 31 is provided with a large number of pixels which are arrayed in a matrix as in the case of a transmission-type liquid crystal display device for example, so that the beam emitted from this spatial beam modulator 31 can be switched from the P-polarized beam component to the S-polarized beam component, and vice versa for each pixel. In this manner, the transmission-type spatial beam modulator 31 is designed to emit the information beam provided with a two-dimensional distribution regarding the plane of polarization in conformity with information to be recorded.

The information beam emitted from this spatial beam modulator 31 is then allowed to enter into another polarized beam splitter 32. This polarized beam splitter 32 acts to reflect only the S-polarized beam component out of the previous information beam while allowing the P-polarized beam component to pass therethrough.

The S-polarized beam component that has been reflected by the polarized beam splitter 32 is allowed to pass, as an information beam provided with a two-dimensional intensity distribution, through an electromagnetic shutter 33 and to enter into another polarized beam splitter 37. This information beam is then reflected by the polarized beam splitter 37, and allowed to enter into a halving optical element 38 for optical rotation.

This halving optical element 38 for optical rotation is constructed such that it is partitioned into a right side portion and a left side portion, which differ in optical properties from each other. Specifically, among the information beams, for example, the beam component to be incident on the right side portion of this halving optical element 38 is allowed to emit therefrom after the plane of polarization thereof has been rotated by an angle of +45°, while the beam component to be incident on the left side portion of this halving optical element 38 is allowed to emit therefrom after the plane of polarization thereof has been rotated by an angle of −45°. The beam component to be derived from the S-polarized beam component whose polarization plane has been rotated by an angle of +45° (or the beam component to be derived from the P-polarized beam component whose polarization plane has been rotated by an angle of −45°) will be hereinafter referred to as an A-polarized beam component, the beam component to be derived from the S-polarized beam component whose polarization plane has been rotated by an angle of −45° (or the beam component to be derived from the P-polarized beam component whose polarization plane has been rotated by an angle of +45°) will be hereinafter referred to as a B-polarized beam component. Each of the right and left portions of the halving optical element 38 may be constructed by a half-wavelength plate.

The A-polarized beam component and the B-polarized beam component that have been emitted from the halving optical element 38 are converged on the reflection layer 22 of a holographic recording medium 21 by an objective lens 34. The holographic recording medium 21 is arranged such that the transparent substrate 25 faces the objective lens 34.

On the other hand, a portion of the P-polarized beam component (reference beam) that has passed through the polarized beam splitter 29 is reflected by the beam splitter 39 and then allowed to pass through the polarized beam splitter 37. This reference beam that has passed through the polarized beam splitter 37 is then incident on the halving optical element 38. The beam component to be incident on the right side portion of this halving optical element 38 is allowed to emit therefrom as a B-polarized beam component after the plane of polarization thereof has been rotated by an angle of +45°while the beam component to be incident on the left side portion of this halving optical element 38 is allowed to emit therefrom as an A-polarized beam component after the plane of polarization thereof has been rotated by an angle of −45°. Subsequently, these A-polarized beam component and B-polarized beam component are converged on the reflection layer 22 of the holographic recording medium 21 by the objective lens 34.

As described above, the information beam constituted by the A-polarized beam component and the reference beam constituted by the B-polarized beam component are emitted from the right side portion of the halving optical element 38. On the other hand, the information beam constituted by the B-polarized beam component and the reference beam constituted by the A-polarized beam component are emitted from the left side portion of the halving optical element 38. Furthermore, these information beam and reference beam are converged on the reflection layer 22 of the holographic recording medium 21.

Therefore, the interference between the information beam and the reference beam takes place only between the information beam formed of the direct beam that has been directly incident on the recording layer 26 through the transparent substrate 25 and the reference beam formed of the reflection beam that has been reflected by the reflection layer 22, and between the reference beam formed of a direct beam and the information beam formed of a reflection beam. Furthermore, not only the interference between the information beam formed from a direct beam and the information beam formed from a reflection beam, but also the interference between the reference beam formed from a direct beam and the reference beam formed from a reflection beam cannot take place. Therefore, according to the recording/reproducing apparatus shown in FIG. 4, it is possible to generate a distribution of optical properties in the recording layer 26 in conformity with the information beam.

In the case of the reflection-type holographic recording/reproducing apparatus shown in FIG. 4, it is possible to provide the apparatus with the ultraviolet source device and the ultraviolet irradiating optical system as already explained above in order to enhance the stability of the recorded hologram.

The information recorded according to the above-mentioned method can be read out as explained below. Namely, the electromagnetic shutter 33 is closed to enable only the reference beam to be emitted, thus irradiating the recording layer 26 having information recorded in advance therein with only the reference beam. As a result, only the reference beam formed of the P-polarized beam component reaches the halving optical element 38.

Owing to the effects of the halving optical element 38, this reference beam is processed such that the beam component having been incident on the right side portion of this halving optical element 38 is emitted therefrom as a B-polarized beam component after the plane of polarization thereof has been rotated by an angle of +45°, while the beam component having been incident on the left side portion of this halving optical element 38 is emitted therefrom as an A-polarized beam component after the plane of polarization thereof has been rotated by an angle of −45°. Subsequently, these A-polarized beam component and B-polarized beam component are converged on the reflection layer 22 of the holographic recording medium 21 by the objective lens 34.

In the recording layer 26 of the holographic recording medium 21, there is formed, according to the above-mentioned method, a distribution of optical properties created in conformity with the information to be recorded. Accordingly, a part of these A-polarized beam component and B-polarized beam component that have been incident on the holographic recording medium 21 is diffracted by the distribution of optical properties created in the recording layer 26 and is then emitted as a reproducing beam from the holographic recording medium 21.

The reproducing beam, emitted from the holographic recording medium 21, reproduces the information beam therein, so that the reproducing beam is formed into a parallel beam by the objective lens 34 and then allowed to reach the halving optical element 38. The B-polarized beam component having been incident on the right side portion of the halving optical element 38 is emitted therefrom as the P-polarized beam component. Further, the A-polarized beam component having been incident on the left side portion of the halving optical element 38 is emitted therefrom also as the P-polarized beam component. In this manner, it is possible to obtain a reproducing beam as the P-polarized beam component.

Then, the reproducing beam passes through the polarized beam splitter 37. Part of the reproducing beam that has passed through the polarized beam splitter 37 is then allowed to pass through the beam splitter 39 and transmitted through an image-forming lens 35 to a two-dimensional beam detector 36, thereby reproducing an image of the transmission-type spatial beam modulator 31 on the two-dimensional beam detector 36. In this manner, it is possible to read out the information recorded in the holographic recording medium 21.

On the other hand, the rests of the A-polarized beam component and of the B-polarized beam component that have transmitted through the halving optical element 38 into the holographic recording medium 21 are reflected by the reflection layer 22 and emitted from the holographic recording medium 21. These A-polarized beam component and B-polarized beam component that have been reflected as a reflection beam are then turned into a parallel beam by the objective lens 34. Subsequently, the A-polarized beam component of this parallel beam is incident on the right side portion of the halving optical element 38 and then emitted therefrom as the S-polarized beam component, while the B-polarized beam component of this parallel beam is incident on the left side portion of the halving optical element 38 and then emitted therefrom as the S-polarized beam component. Since the S-polarized beam component thus emitted from the halving optical element 38 is reflected by the polarized beam splitter 37, it is impossible for the S-polarized beam component to reach the two-dimensional beam detector 36. Therefore, according to this recording/reproducing apparatus, it is now possible to realize an excellent reproducing signal-to-noise ratio.

The holographic recording medium according to the embodiment of the invention can be suitably employed for the multi-layer optical recording and reproducing information. This multi-layer optical recording and reproducing information may be of any type, i.e., either the transmission type or the reflection type.

Next, the present invention will be further explained with reference to specific examples as follows.

### Synthesis Example 1

A stirring bar was put into a three-neck flask to replace the atmosphere thereof with an argon gas. 4.04 g (11.36 mmol) of powdered methyl triphenyl phosphonium bromide (MTPPB) was then put in the flask, and the flask was maintained at a temperature of −10 to 0° C.

120 ml of ether was added using syringe to stir for 10 minutes, dissolving MTPPB. Then, 8.16 ml of 1.6M-butyllithium hexane solution were added slowly, and were stirred for 10 minutes. On the other hand, 2.6705 g of bromonaphthaldehyde was dissolved in 120 ml of ether to obtain a solution. The solution was dropped in the flask over 10 min. Then after stirring for 1 hour, the solution in the flask was heated gradually to room temperature to be hold for about 3 hours.

Next, after dropping a small amount of methanol in the reaction solution to check deactivation of butyllithium, about 100 ml of water was dropped slowly. The reaction solution was moved to a separating funnel to separate a separate phase from the aqueous phase of the solution, forming two layers of an ether layer and an aqueous layer in the separating funnel. The aqueous layer was extracted 3 times with 50 ml of ether, and the ether layer obtained was dried with magnesium sulfate for about 24 hours. After filtering the ether layer on the next day, the ether layer was condensed using an evaporator.

After diluting the condensed solution with about 30 ml of hexane, the solution was filtered to eliminate a hexane-insoluble portion. Next, silica gel column chromatography was carried out using the hexane solvent. Finally, the solution was condensed to weigh, 0.87 g of a product being obtained. This weight corresponds to a yield constant of 33%.

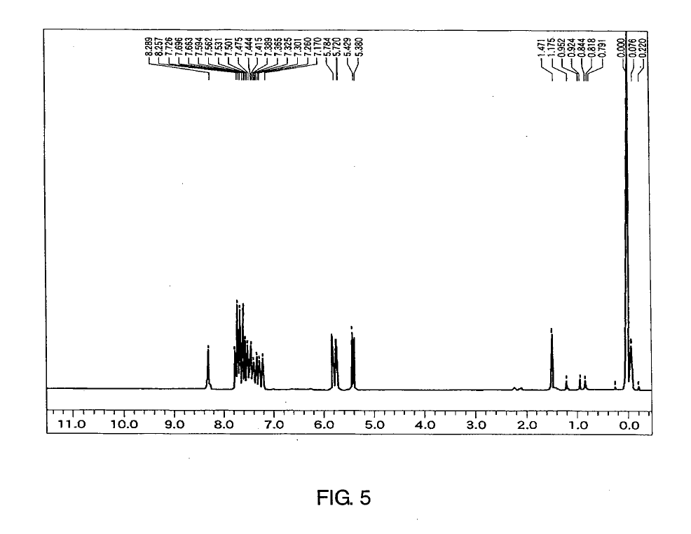

NMR data for the product are shown in FIG. 5. The obtained compound was identified as 1-bromo-2-vinyl naphthalene.

### Synthesis Example 2

1.674 g (45 mmol) of sodium hydroxide and 200 ml of THF were put in a 1000-ml eggplant flask. Then, 4.950 g (45 mmol) of thiophenol dissolved in 50 ml of THF were dropped to the flask with a dropping funnel. Then, after stirring at room temperature for 2 hours, 10.579 g (45 mmol) of bromonaphthaldehyde dissolved in 50 ml of THF were added to further stir for about 3 hours.

Next, after having added 50 ml of water, about 150 ml of THF was volatilized to condense, then an extraction being carried out 3 times with 100 ml of ether. This ethereal solution was dried with magnesium sulfate, and then filtered to condense. Subsequently, a product was isolated using silica gel column chromatography. 2.5 g of phenylthionaphthaldehyde was obtained as a product, corresponding to a yield constant of 21%. From the obtained phenylthionaphthaldehyde, 1-phenylthio-2-vinylnaphthalene was synthesized with the following technique.

A stirring bar was put into a three-neck flask to replace the atmosphere thereof with an argon gas. 3.366 g (9.5 mmol) of powdered methyl triphenyl phosphonium bromide (MTPPB) was then put in the flask, and the flask was maintained at a temperature of −10 to 0° C.

30 ml of ether was added using a syringe to stir for 10 minutes, dissolving MTPPB. 6.8 ml (11.5 mmol) of 1.6M-butyllithium hexane solution were added slowly. Then, the solution became transparent yellow. After stirring for 10 minutes, a solution, which was prepared by having dissolved g of phenylthionaphthaldehyde in 100 ml of ether, was dropped over 10 minutes.

When dropped, precipitation deposited from the yellow solution. The solution changed into a clear, colorless liquid over stirring time. Then after stirring for 1 hour, the solution in the flask was heated gradually up to room temperature over about 3 hours. After dropping a small amount of methanol in the reaction solution to check deactivation of butyllithium, about 100 ml of water was dropped slowly.

The reaction solution was moved to a separating funnel to separate a separate phase from the aqueous phase of the solution, forming two layers of an ether layer and an aqueous layer in the separating funnel. The aqueous layer was extracted 3 times with 50 ml of ether, and the ether layer obtained was dried with magnesium sulfate for about 24 hours. On the next day, after filtering the ether layer, the ether layer was condensed using an evaporator.

After diluting the condensed solution with about 30 ml of hexane, the solution was filtered to eliminate a hexane-insoluble portion. Next, silica gel column chromatography was carried out using a hexane solvent for isolation. The isolation yielded 0.446 g of product, corresponding to a yield constant of 18%.

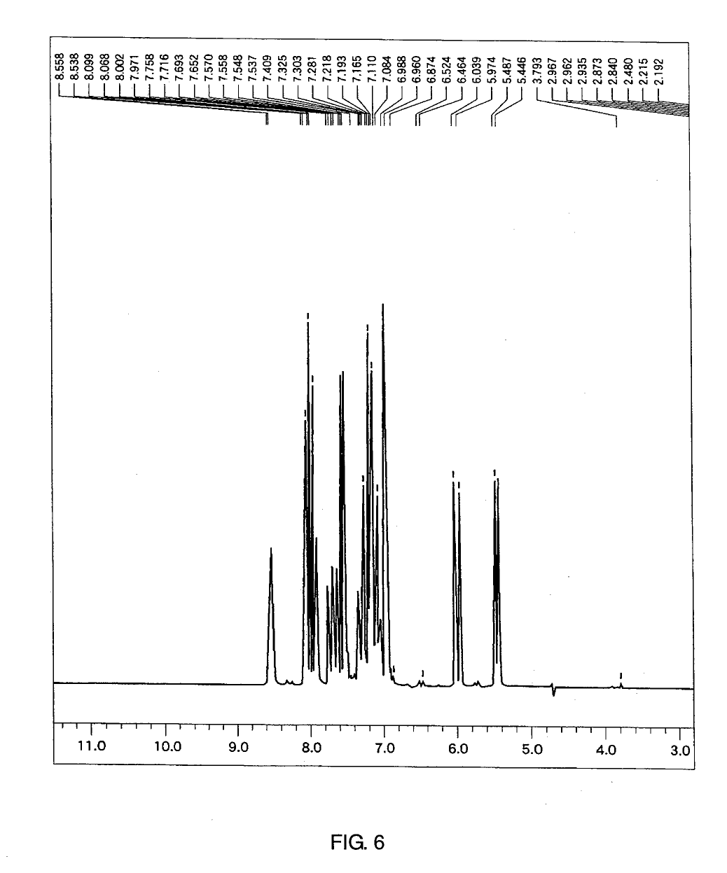

NMR data for the product are shown in FIG. 6. The obtained product was identified as 1-phenylthio-2-vinyl naphthalene.

In the following examples, the holographic recording medium was produced using the obtained polymerizable monomer.

### Example 1

4.54 g of 1,6-hexanediol diglycidyl ether (epoxy equivalent: 151; Nagase Chemitechs Co., Ltd.) employed as an epoxy monomer and 0.364 g of aluminum tris(ethylacetyl acetate) employed as a metal complex were mixed with each other in a dark room to obtain a mixture. This mixture was then allowed to dissolve with stirring at a temperature of 60° C. to prepare a solution of the metal complex.

Furthermore, 4.55 g of 1,6-hexane diolglycidylether (which has an epoxy equivalent weight 151 and is manufactured by Nagase chemitex Co. Ltd.) and 0.545 g of triphenyl silanol as alkyl silanol were mixed with each other to obtain a mixture. The mixture was dissolved with stirring at 60° C. to obtain a silanol solution.

The solution of the metal complex and the silanol solution were mixed with each other to further stir. 0.38 g of 1-bromo-2-vinylnaphthalene as a polymerizable monomer and 0.025 g of the photopolymerization initiator were added to the obtained solution. As the photopolymerization initiator, Irgacure 784 (Chiba Speciality Chemicals Co., Ltd.) was employed. Finally, the solution was subjected to defoaming to obtain a raw material solution for the recording layer.

A pair of glass plates were superimposed with a spacer formed of a Teflon (registered trademark) sheet being interposed therebetween to provide a space. The above-mentioned raw material solution for the recording layer was poured into the space. The resultant whole structure mentioned above was heated in a 55° C.-held oven for 6 hours under a light-shielded condition to obtain a test piece of the holographic recording medium with a 200-μm thick recording layer.

Properties of the holographic recording medium were evaluated using a plane-wave measuring device generally used. A semiconductor laser (405 nm) was used as an optical element of the measuring device. An optical spot size on the test specimen was set to 5 mm in diameter for both information and reference beams. Moreover, the recording beam intensity was adjusted so that the intensity became 7 mW/cm² as a total of the information and reference beams.

After finishing the holographic recording, the information beam was shut off, and the test piece was irradiated with only the reference beam, confirming the diffracted beam from the test piece. Thereby, it was confirmed that the transmission-type hologram was recorded.

The recording performance of hologram was evaluated by an M/# (M number) representing a dynamic range of recording. This M/# can be defined by the following formula (1) using ηᵢ. This ηᵢ represents a diffraction efficiency to be derived from i-th hologram when holograms of n pages are subjected to angular multiple recording/reproduction until the recording at the same region in the recording layer of the holographic recording medium becomes no longer possible. This angular multiple recording/reproduction can be performed by irradiating the holographic recording medium with a predetermined beam while rotating the medium.

$$M / \# = {\sum }_{i = 1}^{n} \sqrt{η} i \qquad formula ( 1 )$$

The diffraction efficiency η was defined by the light intensity Iₜ to be detected at the beam detector and the light intensity I_{d} to be detected at another beam detector on the occasion when the holographic recording medium was irradiated with only the reference beam. Namely, the diffraction efficiency ri was defined by an inner diffraction efficiency which can be represented by η=I_{d}/(Iₜ+I_{d}).

As the value of an M/# of the holographic recording medium becomes larger, the dynamic range of recording can be further increased, thus enabling to enhance multiple recording performances.

The M/# of the recording medium of this example was 10.2. After recording, the medium was preserved for one month at 80° C. Then the M/# was tested for the medium, obtaining an M/# of 9.4. As a result, the M/# decreased approximately by 7.8%. If the decreasing rate of the M/# after the one-month preservation at 80° C. is under 15%, it can be said that the recording was stably preserved.

### Example 2

4.54 g of 1,6-hexanediol diglycidyl ether (epoxy equivalent: 151; Nagase Chemitechs Co., Ltd.) employed as an epoxy monomer and 0.364 g of aluminum tris(ethylacetyl acetate) employed as a metal complex were mixed with each other in a dark room to obtain a mixture. This mixture was then allowed to dissolve with stirring at a temperature of 60° C. to prepare a solution of the metal complex.

Further, 4.55 g of 1,6-hexanediol diglycidyl ether (epoxy equivalent: 151; Nagase Chemitechs Co., Ltd.) employed as an epoxy monomer, and 0.545 g of triphenyl silanol employed as alkyl silanol were mixed with each other to obtain a mixture. This mixture was then allowed to dissolve with stirring at a temperature of 60° C. to prepare a silanol solution.

The solution of the metal complex and the silanol solution were mixed with each other to further stir, producing a mixed solution. 0.38 g of 1-phenylsulfenyl-2-vinylnaphthalene as a polymerizable monomer and 0.025 g of a photopolymerization initiator were added to the mixed solution thus produced. Irgacure 784 (Ciba Speciality Chemicals Co., Ltd.) was employed as the photopolymerization initiator. Finally, the resultant mixture was subjected to defoaming to obtain a raw material solution for the recording layer. A pair of glass plates were superimposed with a spacer formed of a Teflon (registered trademark) sheet being interposed therebetween to provide a space. Then, the above-mentioned raw material solution for the recording layer was poured into this space. The resultant whole structure was heated in a 55° C.-held oven for 6 hours under a light-shielded condition, thereby manufacturing a test piece of the holographic recording medium with a 200-μm thick recording layer.

In this example, the M/# of the recording medium was 10.5. After recording, the medium was preserved for one month at 80° C. Then the M/# was tested for the medium, obtaining an M/# of 9.6. The M/# decreased approximately by 8.6%.

### Example 3

4.35 g of 1,6-hexanediol diglycidyl ether (epoxy equivalent: 151; Nagase Chemitechs Co., Ltd.) employed as an epoxy monomer and 0.364 g of aluminum tris(ethylacetyl acetate) employed as a metal complex were mixed with each other in a dark room to obtain a mixture. This mixture was then allowed to dissolve with stirring at a temperature of 60° C., preparing a solution of the metal complex.

Further, 4.35 g of 1,6-hexanediol diglycidyl ether (epoxy equivalent: 151; Nagase Chemitechs Co., Ltd.) employed as an epoxy monomer, and 0.545 g of triphenyl silanol employed as alkyl silanol were mixed with each other to obtain a mixture. This mixture was then allowed to dissolve with stirring at a temperature of 60° C., thus preparing a silanol solution.

The solution of the metal complex and the silanol solution were mixed with each other with stirring. 0.38 g of 1-bromo-2-vinylnaphthalene as a polymerizable monomer, 0.38 g of 2-vinylnaphthalene, and 0.025 g of a photopolymerization initiator were added to the mixed solution thus obtained. Irgacure 784 (Ciba Speciality Chemicals Co., Ltd.) was employed as the photopolymerization initiator. Finally, the resultant mixture was subjected to defoaming to obtain a raw material solution for the recording layer. A pair of glass plates were superimposed with a spacer formed of a Teflon (registered trademark) sheet being interposed therebetween to provide a space. Then, the above-mentioned raw material solution for the recording layer was poured into this space. The resultant whole structure was heated in a 55° C.-held oven for 6 hours under a light-shielded condition, thereby manufacturing a test piece of the holographic recording medium with a 200-μm thick recording layer.

In this example, the M/# of the recording medium was 17.0. After recording, the medium was preserved for one month at 80° C. Then the M/# was tested for the medium, obtaining an M/# of 15.2. The M/# decreased approximately by 10.6%.

### Example 4

In this example, the holographic recording medium was produced as well as in the example 1, except having changed the polymerizable monomer into 2-methyl-1-vinylnaphthalene. The M/# of the recording medium of this example was 9.0. After recording, the medium was preserved for one month at 80° C. Then the M/# was tested for the medium, obtaining an M/# of 8.2.

### Example 5

In this example, the holographic recording medium was produced as well as in the example 1, except having changed the polymerizable monomer into 2-methyl-1-vinylnaphthalene. The M/# of the recording medium of this example was 9.0. After recording, the medium was preserved for one month at 80° C. Then the M/# was tested for the medium, obtaining an M/# of 8.1. The M/# decreased approximately by 10%.

### Comparative Example 1

In a first modified example, the holographic recording medium was produced as well as in the example 1, except having changed the polymerizable monomer into 2-vinylnaphthalene. The polymerizable monomer employed in the modified example does not include nonpolymerizable substituent groups.

The M/# of the recording medium of this example was 9.0. After recording, the medium was preserved for one month at 80° C. Then the M/# was tested for the medium, obtaining an M/# of 8.2. The M/# decreased by 21%, meaning an unacceptable level of decrease.

### Comparative Example 2

In a second modified example, the holographic recording medium was produced as well as in the example 1, except having changed the polymerizable monomer into 4-methyl-2-vinylnaphthalene. The polymerizable monomer employed in the second modified example does include nonpolymerizable substituent groups. However, a carbon atom with nonpolymerizable monomers chemically binding thereto is not adjacent to a carbon atom to which polymerizable monomers bind chemically.

The M/# of the recording medium of this example was 9.0. After recording, the medium was preserved for one month at 80° C. Then the M/# was tested for the medium, obtaining an M/# of 7.2. The M/# decreased by 21%, meaning an unacceptable level of decrease.

From comparisons of the examples with the comparative example 1, it should be noted that the holographic recording medium containing polymerizable monomer with nonpolymerizable substituent groups has a long-term stability to record information, enhancing the recording performance of the medium. From the comparison of the comparative example 2 with the examples, the following has been clarified. That is, it is important that the polymerizable monomer employed contains nonpolymerizable substituent groups in the holographic recording medium. However, the nonpolymerizable substituent groups may not enhance the recording performance unless a carbon atom with the nonpolymerizable monomers chemically binding thereto is adjacent to a carbon atom to which the polymerizable monomers bind chemically.

What is claimed is:

1. A holographic recording medium comprising a recording layer, the recording layer including:
a polymer matrix;
a polymerizable monomer including a monomer being expressed in the following general formula (M1), (M2), or (M3); and
a photopolymerization initiator,
wherein A and B represent a polymerizable substituent group and a nonpolymerizable substituent group, respectively.

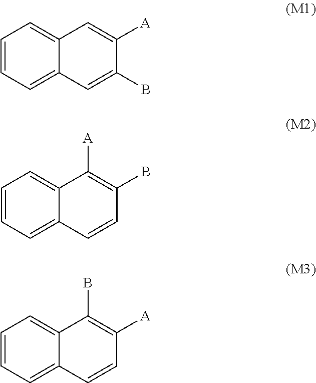

2. The medium according to claim 1, wherein the polymer matrix is a three-dimensional cross-linking polymer.

3. The medium according to claim 1, wherein the nonpolymerizable substituent group in the polymerizable monomer is selected from the group consisting of a bromo group, a methylthio group and a phenylthio group.

4. The medium according to claim 2, wherein the nonpolymerizable substituent group in the polymerizable monomer is selected from the group consisting of a bromo group, a methylthio group and a phenylthio group.

5. The medium according to claim 1, wherein a refractive index of the polymerizable monomer is not less than 1.6 and not more than 1.8.

6. The medium according to claim 2, wherein a refractive index of the polymerizable monomer is not less than 1.6 and not more than 1.8.

7. The medium according to claim 3, wherein a refractive index of the polymerizable monomer is not less than 1.6 and not more than 1.8.

8. The medium according to claim 1, wherein a refractive index of the polymer matrix is not less than 1.4 and not more than 1.6.

9. The medium according to claim 2, wherein a refractive index of the polymer matrix is not less than 1.4 and not more than 1.6.

10. The medium according to claim 3, wherein a refractive index of the polymer matrix is not less than 1.4 and not more than 1.6.

11. The medium according to claim 5, wherein a refractive index of the polymer matrix is not less than 1.4 and not more than 1.6.

12. The medium according to claim 2, wherein the three-dimensional cross-linking polymer matrix includes a structure being expressed in the following general formula (1), and n is not less than 3 and not more than 16.

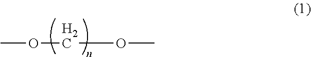

13. An optical information recording/reproducing apparatus comprising:
the holographic recording medium according to claim 1;
a recording portion for recording information in the medium; and
a reproducing portion for reproducing the information recorded in the medium.
